(19) United States
(12) Patent Application Publication
(10) Pub. No.: US 2026/0362794 A1
(43) Pub. Date: Nov. 12, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Hsien-Chih Huang, Hsinchu City (TW); Guan-Lin Chen, Hsinchu County (TW); Wen-Ting Lan, Hsinchu City (TW); Kuo-Cheng CHIANG, Hsinchu County (TW); Chih-Hao Wang, Hsinchu County (TW)

(73) Assignee: Taiwan Semiconductor Manufacturing Company, Ltd., Hsinchu (TW)

(21) Appl. No.: 19/205,940

(22) Filed: May 12, 2025

(51) Int. Cl. H10D 84/83; H10D 30/00; H10D 30/01; H10D 30/43; H10D 62/10; H10D 62/13; H10D 64/01; H10D 84/01

(52) U.S. Cl. CPC H10D 84/832; H10D 30/014; H10D 30/0191; H10D 30/43; H10D 30/503; H10D 62/121; H10D 62/151; H10D 64/021; H10D 84/013; H10D 84/0147; H10D 84/0149

(57) ABSTRACT

A semiconductor device includes a first semiconductor fin and a second semiconductor fin extending along a first direction, an isolation structure disposed between the first and second semiconductor fins, a first epitaxial structure and a second epitaxial structure respectively disposed over the first and second semiconductor fins, and a sidewall spacer layer including a first portion and a second portion. Each of the first and second epitaxial structures includes a height measured along the first direction and a width measured along the second direction and different from the height. The first portion extends along the first direction and lines bottoms of the first and second epitaxial structures, the second portion is connected to the first portion and extends along a second direction that is substantially perpendicular to the first portion, and a portion of each of the first and second epitaxial structures overhangs the sidewall spacer layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17B illustrate schematic various views of intermediate steps during a process for forming a semiconductor device, in accordance with some embodiments.

FIG. 18 illustrates schematic cross-sectional view of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Terms “first”, “second”, “third”, “fourth”, and the like are merely generic identifiers and, as such, may be interchanged in various embodiments.

The embodiments of the disclosure describe a manufacturing process of a semiconductor device (or a portion of a nanostructure transistor device). The nanostructure transistor device (also referred to as a gate-all-around (GAA) transistor device) may include a gate structure wrapping around the perimeter of one or more nanostructures (i.e. channel regions) for improved control of channel current flow. The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The embodiments are not limited in this context. The semiconductor device may be included in microprocessors, memories, and/or other integrated circuits (IC). Accordingly, it is understood that additional processes may be provided before, during, and after the illustrated method, and that some other processes may only be briefly described herein. Also, the structures illustrated in the drawings are simplified for a better understanding of the concepts of the present disclosure. For example, although the figures illustrate the structure of the semiconductor device, it is understood the semiconductor device may be part of an IC that further includes a number of other devices such as resistors, capacitors, inductors, fuses, etc.

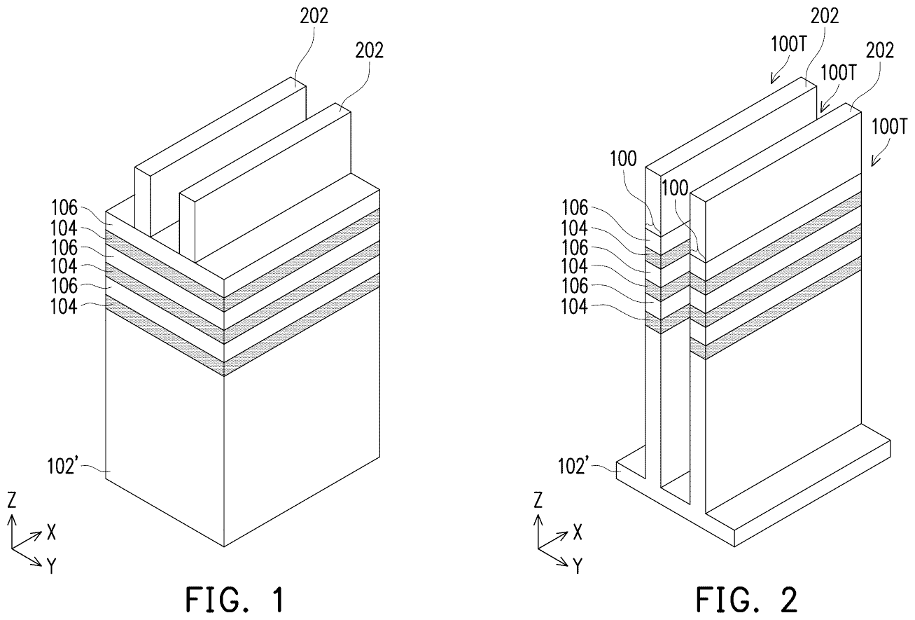

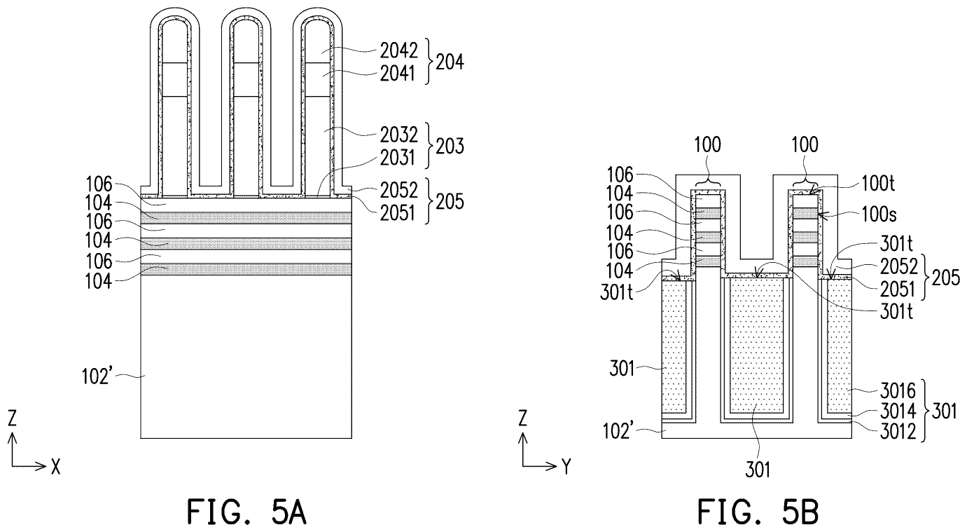

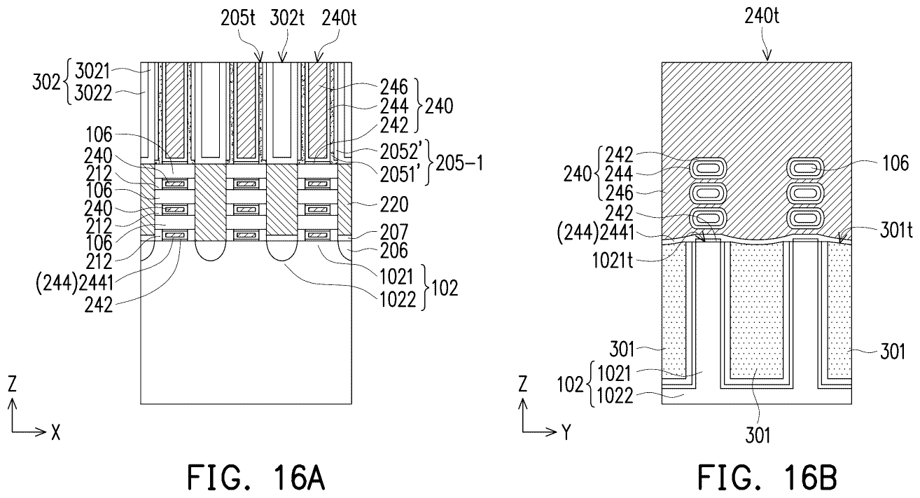

FIGS. 1-17B illustrate schematic various views of intermediate steps during a process for forming a semiconductor device, in accordance with some embodiments. For clarity of illustrations, in the drawings are illustrated the directions (e.g., X, Y, and Z) of the coordinate system according to which the views are oriented, where the X-direction, the Y-direction, and the Z-direction are substantially perpendicular to one another. It should be noted that FIGS. 1-4 are schematic perspective views of intermediate steps during a process for forming a semiconductor device, FIGS. 5A, 6A, 7A, 8A, 9A, 10A, 11A, 12A, 13A, 14A, 15A, 16A, and 17A are schematic cross-sectional views of various stages of manufacturing the semiconductor device taken along line A-A of FIG. 4, FIGS. 5B, 6B, 7B, 8A, 9B, 10B, 11B, 12B, 13B, 14B, 15B, and 17B are schematic cross-sectional views of various stages of manufacturing the semiconductor device taken along line B-B of FIG. 4, and FIG. 16B is a schematic cross-sectional view of one of various stages of manufacturing the semiconductor device taken along line C-C of FIG. 4, in accordance with some embodiments.

Referring to FIG. 1, a stack of first semiconductor layers 104 and second semiconductor layers 106 may be formed on a semiconductor substrate 102′. In some embodiments, the semiconductor substrate 102′ includes a crystalline silicon substrate or a bulk silicon substrate (e.g., wafer). In some embodiments, the semiconductor substrate 102′ is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102′ includes a semiconductor-on-insulator (SOI) substrate. The semiconductor substrate 102′ may include various doped regions (not individually shown) doped with p-type or n-type dopants, where the doped regions may be configured for an n-type field effect transistor (FET), or alternatively, configured for a p-type FET.

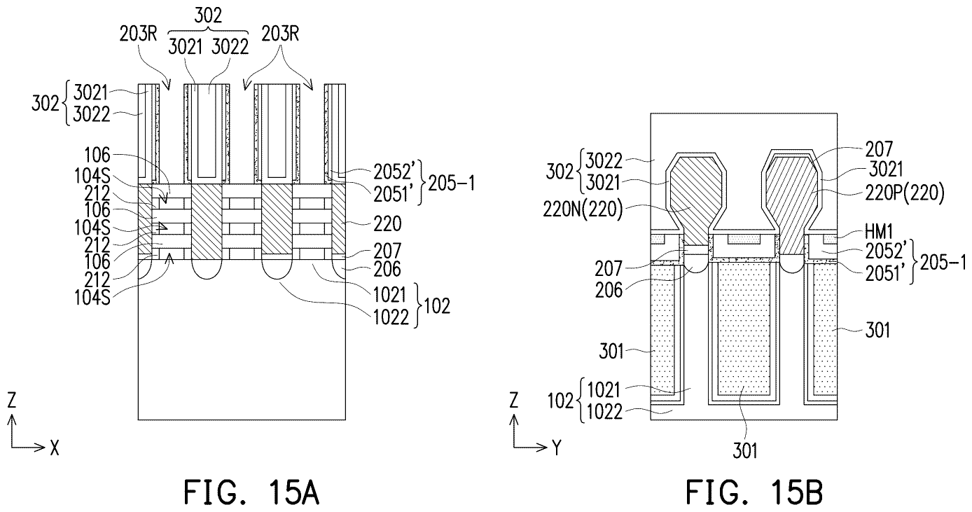

With continued reference to FIG. 1, the first semiconductor layers 104 and the second semiconductor layers 106 may be alternately stacked upon one another (e.g., along the direction D3) to form a stack. The first semiconductor layers 104 may be considered sacrificial layers in the sense that they are removed in the subsequent process (see FIG. 15A). In some embodiments, the bottommost one of the first semiconductor layers 104 is formed on the semiconductor substrate 102′, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102′), and either the first semiconductor layer 104 or the second semiconductor layer 106 may be the topmost layer (or the layer most distanced to the semiconductor substrate 102′). The disclosure is not limited by the number of stacked semiconductor layers (e.g., 104 and 106).

With continued reference to FIG. 1, the first semiconductor layers 104 and the second semiconductor layers 106 may have different materials (or compositions) that may provide for different oxidation rates and/or different etch selectivity between the layers. For example, the second semiconductor layers 106 are formed of the same material as the semiconductor substrate 102′, while the first semiconductor layers 104 may be formed of a different material which may be selectively removed with respect to the material of the semiconductor substrate 102′ and the second semiconductor layers 106. In some embodiments, the material of the first semiconductor layers 104 includes silicon germanium. In some embodiments, the second semiconductor layers 106 include silicon, where each of the second semiconductor layers 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets and may be considered as channel regions in the subsequent processes. The terms “semiconductor nanosheets” and “channel regions” may be used interchangeably herein.

Still referring to FIG. 1, a mask layer 202 may be formed over the top of the stack, e.g., on the topmost one of the second semiconductor layers 106. The mask layer 202 may be used to pattern exposed portions of the stack of first semiconductor layers 104 and second semiconductor layers 106 and the underlying semiconductor substrate 102′. The mask layer 202 may be a single layer or include more than one sublayer (e.g., including a first oxygen-containing sublayer overlying the stack, a nitrogen-containing sublayer overlying the first oxygen-containing sublayer, and a second oxygen-containing sublayer overlying the nitrogen-containing sublayer). The mask layer 202 may be formed by any suitable deposition process, such as chemical vapor deposition (CVD) process or the like.

Referring to FIG. 2 and with reference to FIG. 1, a portion of the stack of first semiconductor layers 104 and second semiconductor layers 106 and the underlying portion of the semiconductor substrate 102′ may be removed to form trenches 100T, thereby defining a fin structure 100 between adjacent trenches 100T. Each trench 100T may be disposed between adjacent two of the fin structures 100. For example, the fin structure 100 is formed by etching the trenches 100T at exposed portions of the stack of first semiconductor layers 104 and second semiconductor layers 106 and the semiconductor substrate 102′ which are not covered by the mask layer 202, wherein the mask layer 202 serves as an etch mask for protecting the underlying structure. The etching process may include dry etching, wet etching, reactive ion etching (RIE), and/or other suitable processes. As shown in FIG. 2, two fin structures 100 are formed, but the number of the fin structures 100 is not limited to two.

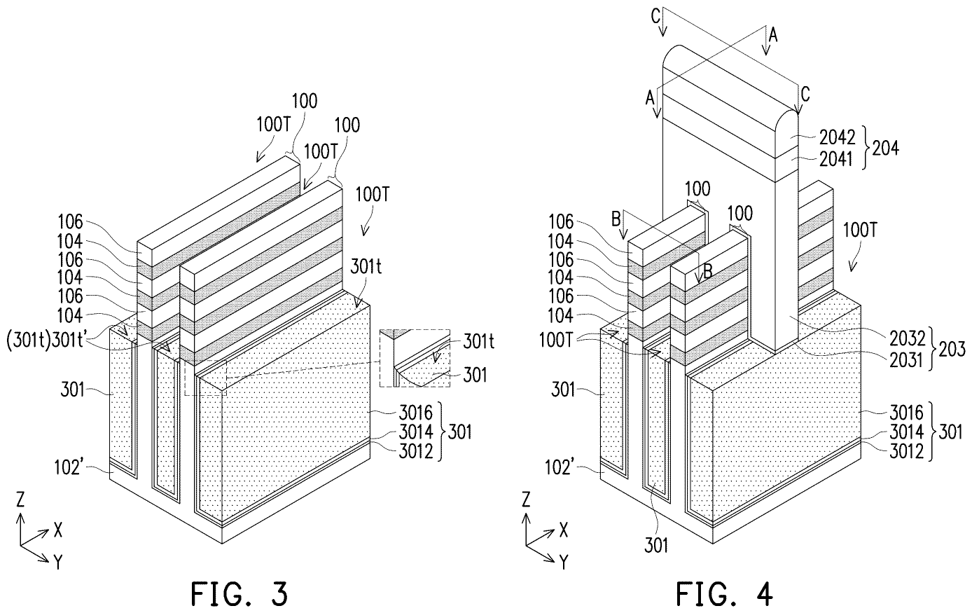

Referring to FIG. 3 and with reference to FIG. 2, a plurality of isolation structures 301 (also referred to as shallow trench isolation (STI) structures) may be formed in lower portions of the trenches 100T. For example, the isolation structures 301 extend at opposing sides of the lower portion of the semiconductor substrate 102′. In some embodiments, each of the isolation structures 301 is disposed between adjacent two of the fin structures 100 and covers a sidewall of the lower portion of the respective fin structure 100. The isolation structures 301 may each be formed of one or more insulation material(s) (e.g., an oxide, a Si-based oxide, a nitride, the like, any other suitable material(s), combinations thereof, etc.) which may electrically isolate neighboring fin structures 100 from each other.

In some embodiments, the respective isolation structure 301 includes a first liner 3012, a second liner 3014 overlying the first liner 3012, and a filling layer 3016 overlying the second liner 3014. For example, the sidewall and the bottom surface of the lower portion of the respective fin structure 100 are lined with the first liner 3012. In some embodiments, the first liner 3012 has a thickness ranging from about 0.3 nm to about 5 nm. The material of the first liner 3012 may include SiN, SiON, SiCN, SiCON, or other suitable dielectric material(s). The second liner 3014 may be conformally formed on the first liner 3012. In some embodiments, the second liner 3014 has a thickness ranging from about 0.3 nm to about 5 nm. In some embodiments, the material of the second liner 3014 is selected from the group of candidate dielectric materials of the first liner 3012. The second liner 3014 has a different material than the first liner 3012. In alternative embodiments, the second liner 3014 and the first liner 3012 are made of the same dielectric material. It is realized that the thicknesses provided herein are examples, and may be changed to other suitable values depending on process and product requirements.

With continued reference to FIG. 3, the filling layer 3016 may be formed on the second liner 3014 and fill the rest space between adjacent two of the fin structures 100. In some embodiments, the filling layer 3016 has a different dielectric material than the second liner 3014. For example, the filling layer 3016 includes SiOx, SiON, SiCO, SiCON, or other suitable dielectric material(s). In some embodiments, the material of the filling layer 3016 has a dielectric constant that is about 3 to about 5. The filling layer 3016 may be formed by a low-thermal-budget process. It is appreciated that when geometry sizes of ICs are getting smaller and smaller, a thermal budget of processes in IC fabrication presents new challenges. As an example, when a high temperature process is used in the formation of the isolation structures, deformations of existing fine features may occur. It is desired to have improvements in this area. For example, a low-thermal-budget annealing process is performed on the isolation structures 301, thereby reducing or eliminating the issues caused by high-temperature process performed on the isolation structure. In some alternative embodiments, the step of annealing the isolation structure 301 is omitted.

Still referring to FIG. 3 and FIG. 2, the isolation structures 301 may be formed by: depositing layers of insulation materials (e.g., the materials of the first liner 3012, the second liner 3014, and the filling layer 3016) in the respective trench 100T; and recessing the layers of insulation materials using an acceptable etching process, such as one that is selective to the material(s) of the isolation structures 301. During the recessing, the mask layer 202 may protect the underlying fin structures 100. The isolation structures 301 may be recessed, and thus the fin structure 100 is protruded from the neighboring isolation structures 301. As shown in the enlarged view of FIG. 3, the top surfaces 301t of the isolation structures 301 may include a flat surface, a non-planar surface (e.g., a convex curved surface, a concave curved surface, etc.), or combinations thereof, depending on the etching process. In some embodiments, the isolation structures 301 include different heights measured along the Z-direction. For example, the top surface 301t′ of one of the isolation structure 301 and the top surface 301t of another one of the isolation structure 301 are not at the same level. After (or during) the formation of the isolation structures 301, the mask layer 202 may be removed from the fin structures 100, and the topmost one of the second semiconductor layers 106 may then be accessibly exposed.

Referring to FIG. 4 and with reference to FIG. 3, a dummy gate structure 203 may be formed on the fin structures 100. The dummy gate structure 203 may also be formed in the trenches 100T and on the isolation structures 301. The dummy gate structure 203 may have the lengthwise direction along the Y-direction which is substantially perpendicular to the lengthwise direction (e.g., the X-direction) of the respective fin structure 100. In some embodiments, the dummy gate structure 203 includes a dummy dielectric layer 2031 covering the fin structures 100 and the isolation structures 301 and a dummy gate layer 2032 formed on the dummy dielectric layer 2031. In some embodiments, the dummy dielectric layer 2031 covers the top surfaces 301t of the isolation structures 301 and may extend between the dummy gate layer 2032 and the isolation structures 301. The dummy dielectric layer 2031 may be or include silicon oxide, silicon nitride, a combination thereof, or the like, and may be deposited or thermally grown according to acceptable techniques. The dummy gate layer 2032 may include conductive material(s) or non-conductive material(s) and may be selected from a group including amorphous silicon, polysilicon, poly-crystalline silicon-germanium, metallic oxides, and metals, and may be formed by using physical vapor deposition (PVD), chemical vapor deposition (CVD), atomic layer deposition (ALD), sputtering, or other suitable techniques.

With continued reference to FIG. 4, a mask layer 204 may be formed on the dummy gate structure 203. The mask layer 204 may be a single mask layer or include multiple sublayers formed of different materials including silicon nitride, silicon oxynitride, or the like. In the illustrated embodiment, the mask layer 204 includes a first mask sublayer 2041 overlying the dummy gate structure 203 and a second mask sublayer 2042 overlying the first mask sublayer 2041. For example, one or more mask material(s) may be formed and then patterned using acceptable lithography and etching techniques to form the mask layer 204. Next, the pattern of the mask layer 204 may be transferred to the dummy gate structure 203 as shown in FIG. 4.

Referring to FIGS. 5A-5B and with reference to FIG. 4, a sidewall spacer layer 205 may be formed on sidewalls of the mask layer 204 and the dummy gate structure 203 as shown in the cross-sectional view of FIG. 5A. For example, the sidewall spacer layer 205 is disposed on the sidewalls 203s of the dummy gate structure 203 and extends to cover sidewalls 204s of the mask layer 204. In some embodiments, the sidewall spacer layer 205 is disposed on the sidewalls 100s and the top surface 100t of the respective fin structure 100 and extends to cover the top surface 301t of the respective isolation structure 301, as shown in the cross-sectional view of FIG. 5B. The sidewall spacer layer 205 may be deposited by thermal oxidation or deposited by CVD, ALD, PVD, or the like. The sidewall spacer layer 205 may act to self-align subsequently formed source/drain (S/D) regions, as well as to protect sidewalls of the respective fin structure 100 during subsequent processing.

The sidewall spacer layer 205 may be a single layer or may include multiple sublayers formed of different materials. In some embodiments, the sidewall spacer layer 205 includes a first sublayer 2051 lining the sidewalls 203s of the dummy gate structure 203 and the sidewalls 204s of the mask layer 204, as shown in the cross-sectional view of FIG. 5A. In the cross-sectional view of FIG. 5B, the sidewalls 100s and the top surface 100t of the respective fin structure 100 and the top surface 301t of the respective isolation structure 301 may be lined with the first sublayer 2051. In some embodiments, the first sublayer 2051 has a thickness ranging from about 0.5 nm to about 10 nm. The material of the first sublayer 2051 may include SiN, SiON, SiCN, SiCON, or other suitable lining material(s). The sidewall spacer layer 205 may include a second sublayer 2052 conformally formed on the first sublayer 2051. The material of the second sublayer 2052 may be selected from the group of candidate dielectric materials of the first sublayer 2051, but the second sublayer 2052 has a different material than the first sublayer 2051. In alternative embodiments, the first sublayer 2051 and the second sublayer 2052 are made of the same material. In some embodiments, the second sublayer 2052 has a thickness ranging from about 0.5 nm to about 10 nm. It is realized that the thicknesses provided herein are examples, and may be changed to other suitable values depending on process and product requirements.

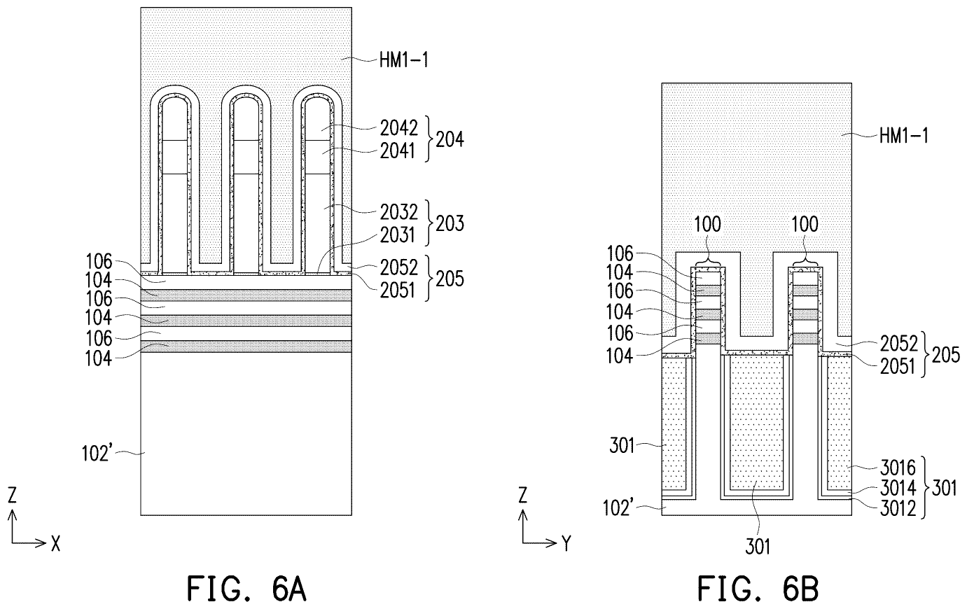

Referring to FIGS. 6A-6B and with reference to FIGS. 5A-5B, a protective layer HM1-1 may be formed on the sidewall spacer layer 205. For example, the protective layer HM1-1 formed on the sidewall spacer layer 205 extends into the gap between adjacent mask layers 204 and the gap between adjacent dummy gate structures 203, as shown in the cross-sectional view of FIG. 6A. In the cross-sectional view of FIG. 6B, the protective layer HM1-1 formed on the sidewall spacer layer 205 may extend into the gap between adjacent fin structures 100. The protective layer HM1-1 may be or include inorganic material(s). For example, the material of the protective layer HM1-1 is or includes suitable dielectric material(s) such as SiN, SiON, SiOC, SiCON, etc. In some embodiments, the protective layer HM1-1 has a different material than the material of the underlying second sublayer 2052 of the sidewall spacer layer 205.

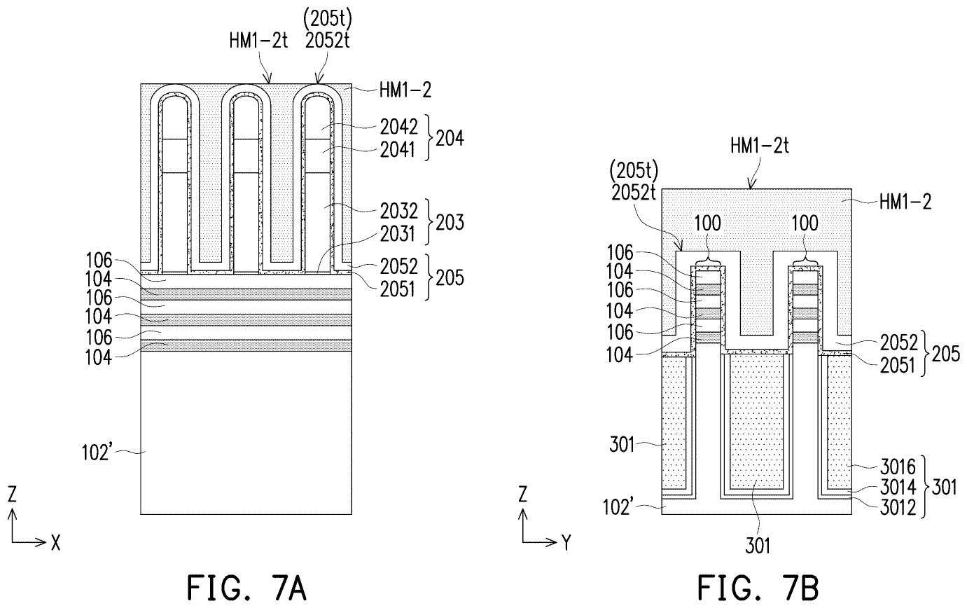

Referring to FIGS. 7A-7B and with reference to FIGS. 6A-6B, a planarization process may be performed to partially remove the protective layer HM1-1 to form a protective layer HM1-2. The planarization process may include a chemical mechanical polishing (CMP) process, a grinding process, an etching process, one or more other applicable processes, or a combination thereof. In some embodiments, after the planarization process, at least a portion of the sidewall spacer layer 205 is exposed by the protective layer HM1-2, as shown in the cross-sectional view of FIG. 7A. For example, the top surface HM1-2t of the protective layer HM1-2 is substantially leveled with the top surface 205t of the sidewall spacer layer 205 (e.g., the top surface 2052t of the second sublayer 2052), within process variations, as shown in the cross-sectional view of FIG. 7A. In the cross-sectional view of FIG. 7B, the protective layer HM1-2 may have a reduced thickness as compared to the protective layer HM1-1 shown in FIG. 6B, and the top surface HM1-2t of the protective layer HM1-2 is above the top surface 205t of the sidewall spacer layer 205 (e.g., the top surface 2052t of the second sublayer 2052).

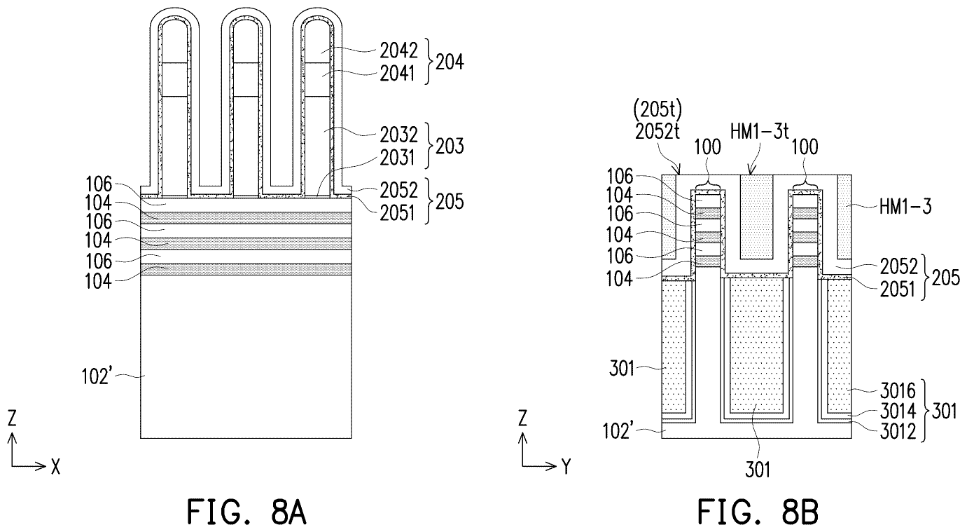

Referring to FIGS. 8A-8B and with reference to FIGS. 7A-7B, one or more etching back processes may be performed to partially remove the protective layer HM1-2 so as to form a protective layer HM1-3. In some embodiments, a portion of the protective layer HM1-2 remaining in the gap between adjacent mask layers 204 and the gap between adjacent dummy gate structures 203 is removed, as shown in the cross-sectional view of FIG. 8A. In the cross-sectional view of FIG. 8B, at least a top portion of the sidewall spacer layer 205 is exposed by the protective layer HM1-3. For example, the top surface HM1-3t of the protective layer HM1-3 is substantially leveled with the top surface 205t of the sidewall spacer layer 205 (e.g., the top surface 2052t of the second sublayer 2052), within process variations.

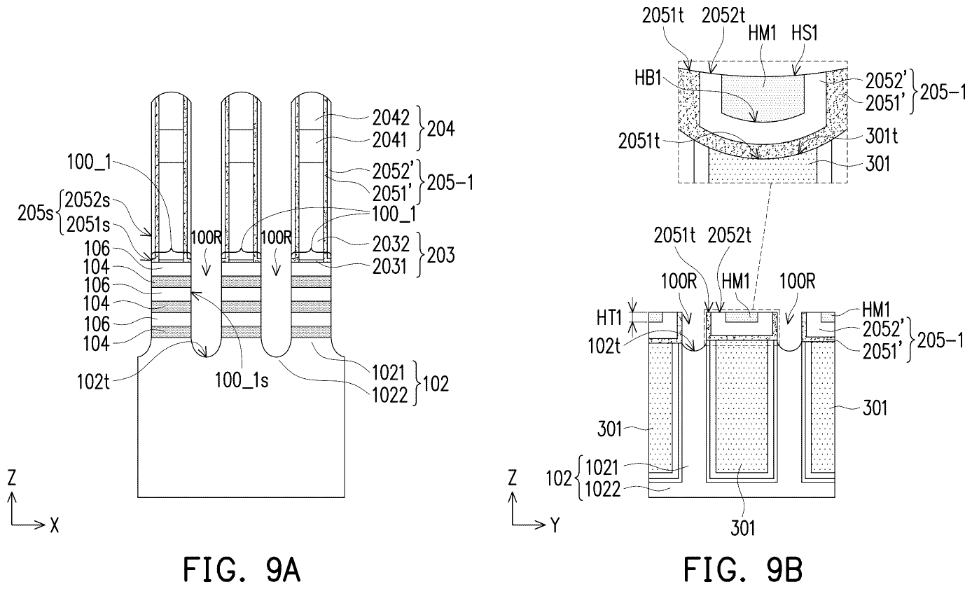

Referring to FIGS. 9A-9B and with reference to FIGS. 8A-8B, a portion of the sidewall spacer layer 205, a portion of the respective fin structure 100, and a portion of the semiconductor substrate 102′ underlying the portion of the respective fin structure 100 may be removed to form recesses 100R, a respective etched fin structure 100_1 between two adjacent recesses 100R, and the sidewall spacer layer 205-1 landing on the periphery of the respective etched fin structure 100_1, as shown in the cross-sectional view of FIG. 9A. The S/D regions will be subsequently formed in the recesses 100R, and thus the recesses 100R may be referred to as S/D recesses. The recesses 100R may be formed by etching the sidewall spacer layer 205, the underlying fin structures 100, and the underlying semiconductor substrate 102′ using suitable etching processes (e.g., anisotropic etching or the like).

With continued reference to FIG. 9A, the respective recess 100R may extend through the sidewall spacer layer 205 and the respective fin structure 100 to respectively form the sidewall spacer layer 205-1 and the etched fin structure 100_1. In some embodiments, an outer sidewall 2051s of the first sublayer 2051′ of the sidewall spacer layer 205-1 and an outer sidewall 2052s of the second sublayer 2052′ of the sidewall spacer layer 205-1 are substantially aligned with a sidewall 100_1s of the respective etched fin structure 100_1. The outer sidewall 2051s of the first sublayer 2051′ and the outer sidewall 2052s of the second sublayer 2052′ may be collectively viewed as an outer sidewall 205s of the sidewall spacer layer 205-1. The respective recess 100R extends further into the underlying semiconductor substrate 102′ to form a semiconductor substrate 102. The semiconductor substrate 102 may include bottom fin portions (also called mesa portions) 1021 and recess portions 1022 laterally connected to adjacent two of the bottom fin portions 1021. The respective recess portion 1022 may have a top surface 102t which can be a flat surface, a curved (e.g., concave) surface, or combinations thereof, depending on the etching process.

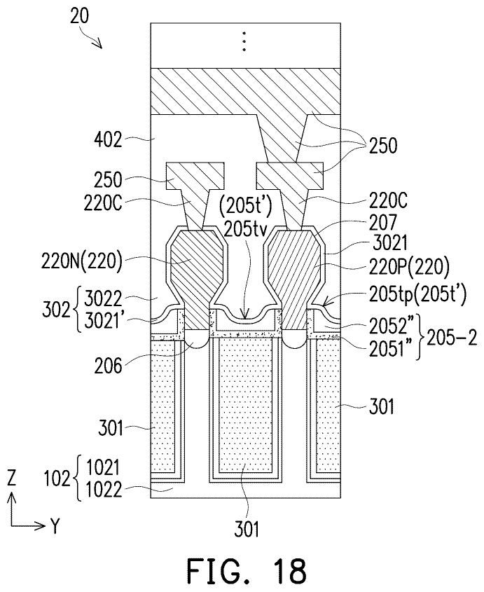

With continued reference to FIG. 9B, the protective layer HM1-3 and the sidewall spacer layer 205 may be partially removed during the formation of the recesses 100R to respectively form the protective layer HM1 and the sidewall spacer layer 205-1. For example, three surfaces (e.g., opposing sidewalls and a bottom surface) of the protective layer HM1 are in physical contact with the second sublayer 2052′ of the sidewall spacer layer 205-1. The maximum thickness HT1 of the protective layer HM1 measured along the Z-direction may be in a range of about 1 nm and about 15 nm. In some embodiments, as shown in the enlarged view of FIG. 9B, the interface between the isolation structure 301 and the first sublayer 2051′ of the sidewall spacer layer 205-1 is non-planar. For example, the top surface 301t of the isolation structure 301 has a concave curved profile, and the first sublayer 2051′ of the sidewall spacer layer 205-1 overlying the top surface 301t may have a concave curved bottom surface 2051t as shown in the enlarged view of FIG. 9B. The bottom surface HB1 of the protective layer HM1 interfacing the second sublayer 2052′ of the sidewall spacer layer 205-1 may be non-planar. In some embodiments, the top surface 2052t of the second sublayer 2052′ of the sidewall spacer layer 205-1 and the top surface 2051t of the first sublayer 2051′ of the sidewall spacer layer 205-1 are exposed by the protective layer HM1. In some embodiments, the top surface 2052t of the second sublayer 2052′ and the top surface 2051t of the first sublayer 2051′ are substantially level with the top surface of the protective layer HM1. In alternative embodiments, each of the top surface 2052t of the second sublayer 2052′, the top surface 2051t of the first sublayer 2051′, and the top surfaceHS1 of the protective layer HM1 is non-planar. For example, the top surface 2052t, the top surface 2051t, and the top surfaceHS1 are concave curved surfaces. In alternative embodiments, the protective layer is fully removed to expose the underlying second sublayer 2052′ of the sidewall spacer layer 205-1 as shown in FIG. 18.

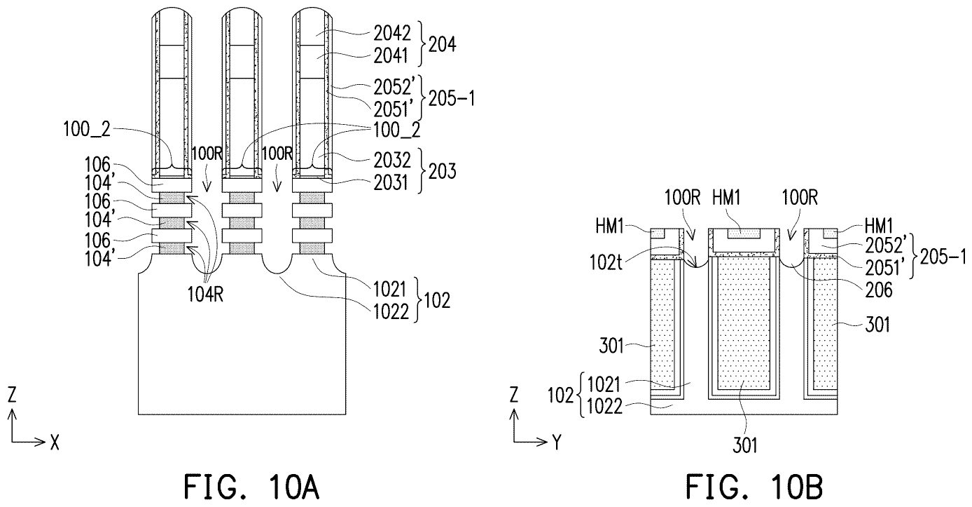

Referring to FIGS. 10A-10B and with reference to FIGS. 9A-9B, portions of the first semiconductor layers 104 exposed by the recesses 100R may be removed in the lateral direction (e.g., the X-direction) to form a respective etched fin structure 100_2 having etched first semiconductor layers 104′. The removal may be performed by using, e.g., isotropic etching processes or other suitable removal techniques. For example, the etchant of the selective etching process is chosen so that the portions of the first semiconductor layers 104 are removed to form lateral recesses 104R, while the second semiconductor layers 106 remain substantially intact during the etching. The respective etched first semiconductor layer 104′ may be laterally recessed from the sidewalls of the underlying (or overlying) second semiconductor layer 106. Although sidewalls of the etched first semiconductor layers 104′ adjacent the lateral recesses 104R are illustrated as being straight in FIG. 10A, the sidewalls of the etched first semiconductor layers 104′ may be concave or convex. Note that the structure in the cross-sectional view of FIG. 10B may be substantially the same as the structure in the cross-sectional view of FIG. 9B.

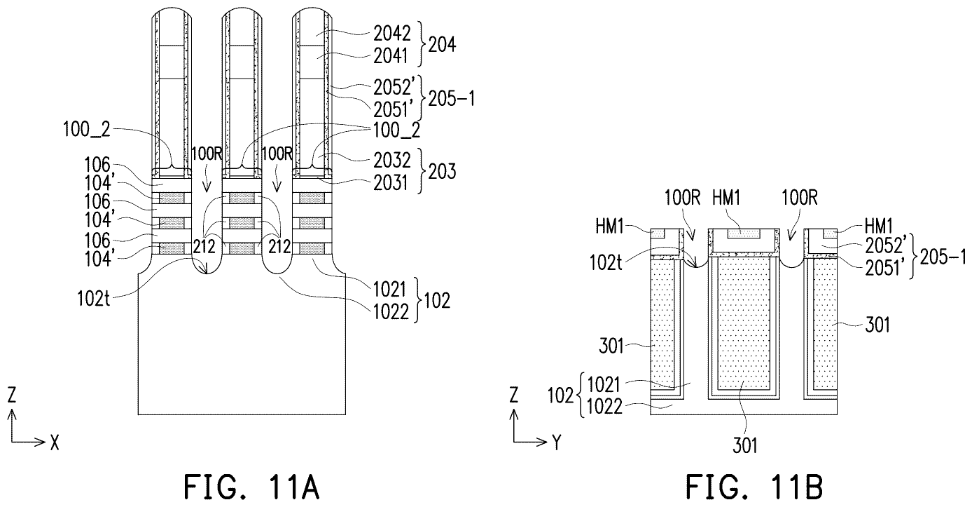

Referring to FIGS. 11A-11B and with reference to FIGS. 10A-10B, inner sidewall spacers 212 may be formed in the lateral recesses 104R alongside the etched first semiconductor layers 104′. For example, the inner sidewall spacers 212 are formed along the etched ends of each of the etched first semiconductor layers 104′ and along respective ends of each of the etched first semiconductor layers 104′ and the second semiconductor layers 106. The inner sidewall spacers 212 may be formed of SiN, SiCN, SiCON, combination thereof, or any other type of dielectric material(s), and may be deposited using, e.g., a conformal deposition process and subsequent etching back to remove excess spacer materials on the sidewalls of the etched fin structure 100_2 and on the top surfaces 102t of the semiconductor substrate 102. In some embodiments, the inner sidewall spacers 212 are formed of a material different from the sidewall spacer layer 205-1. The sidewall spacer layer 205-1 may serve as a mask during the removal of the excess spacer materials, and thus the outer sidewalls of the sidewall spacer layer 205-1 may be substantially aligned with outer sidewalls of the underlying second semiconductor layers 106 and outer sidewalls of the inner sidewall spacers 212. Note that the structure in the cross-sectional view of FIG. 11B may be substantially the same as the structure in the cross-sectional view of FIG. 9B.

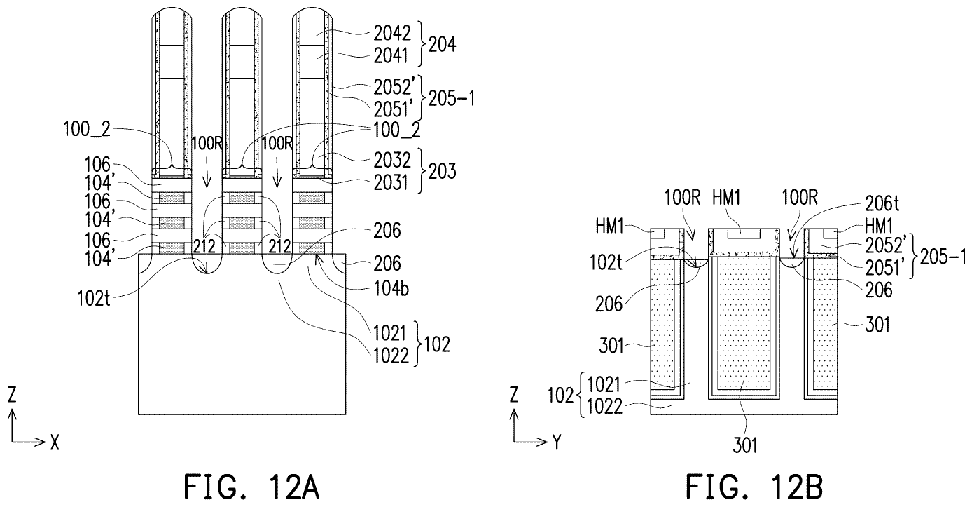

Referring to FIGS. 12A-12B and with reference to FIGS. 11A-11B, semiconductor layers 206 may be formed in the recesses 100R and on the top surfaces 102t of the semiconductor substrate 102. For example, the semiconductor layers 206 are formed on the recess portions 1022 of the semiconductor substrate 102 as shown in the cross-sectional view of FIG. 12A, and may also be formed on the bottom fin portion 1021 of the semiconductor substrate 102 as shown in the cross-sectional view of FIG. 12B. In some embodiments, the material of the semiconductor layers 206 is the same as the material of the semiconductor substrate 102 and/or the material of the second semiconductor layer 106. For example, the semiconductor layers 206 include undoped silicon layers. The semiconductor layers 206 may include other suitable semiconductor material(s) and may be configured to facilitate subsequent fabrication steps for forming epitaxial structures thereon. In some embodiments, the top surface 206t of the respective semiconductor layer 206 is not beyond the bottom surface 104b of the bottommost one of the etched first semiconductor layers 104′, as shown in the cross-sectional view of FIG. 12A.

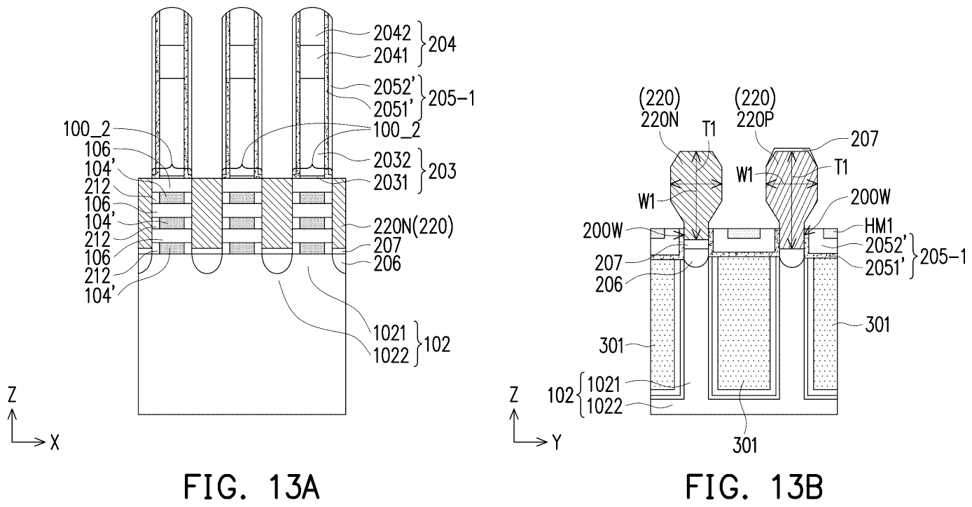

Referring to FIGS. 13A-13B and with reference to FIGS. 12A-12B, epitaxial structures 220 may be formed on/over the semiconductor layers 206 and in the recesses 100R. The epitaxial structures 220 may be coupled to the outer sidewalls of the second semiconductor layers 106 and the inner sidewall spacers 212 along the X-direction, as shown in the cross-sectional view of FIG. 13A. As shown in the cross-sectional view of FIG. 13B, the bottom sidewall 220W of the respective epitaxial structure 220 may be lined with the first sublayer 2051′ of the sidewall spacer layer 205-1. The respective epitaxial structure 220 may have a maximum width W1 measured along the Y-direction and a maximum thickness T1 measured along the Z-direction, and the maximum width W1 and the maximum thickness T1 are different. As a result, a portion of the respective epitaxial structure 220 may overhang the isolation structure 301 and the sidewall spacer layer 205-1 (and the protective layer HM1, if the width W1 is large enough). The respective epitaxial structure 220 may include a crystalline semiconductor material such as silicon germanium, indium arsenide, indium gallium arsenide, indium antimonide, germanium arsenide, germanium antimonide, indium aluminum phosphide, indium phosphide, any other suitable material, or combinations thereof.

The epitaxial structures 220 may be doped with conductive dopants to form S/D features. It should be noted that S/D feature(s) may refer to a source or a drain, individually or collectively dependent upon the context. In addition, the terms “epitaxial structures” and “S/D features” may be used interchangeably herein. In some embodiments, the epitaxial structures 220 are doped with different types of dopants. As shown in the cross-sectional view of FIG. 13B, one of the epitaxial structures 220 (e.g., 220N) is configured for an n-type FET, and the other one of the epitaxial structures 220 (e.g., 220P) is configured for a p-type FET. In alternative embodiments, the epitaxial structures 220 are doped with the same type of dopants (e.g., p-type dopants or n-type dopants) and configured for the same type of FET over certain region of the semiconductor substrate 102, e.g., the embodiment shown in the cross-sectional view of FIG. 13A.

With continued reference to FIGS. 13A-13B, an isolation layer 207 is optionally formed on the semiconductor layer 206, and the epitaxial structures 220 may be formed on the isolation layer 207 as shown in the cross-sectional view of FIG. 13A. In some embodiments, a top surface of the isolation layer 207 is between the top surface and the bottom surface of the bottommost one of the inner sidewall spacers 212, so that the isolation layer 207 covers the bottom fin portion 1021 of the semiconductor substrate 102 while keeping the bottommost one of the second semiconductor layers 106 exposed by the isolation layer 207. The isolation layer 207 may include one or more layers of isolating material(s) such as silicon nitride containing material, such as SiN, SiON, SiOCN, SiOC, SiCN, a metal oxide, or a combination thereof. In some embodiments, the isolation layer 207 is configured to provide electrical isolation between the mesa portion of the semiconductor substrate 102 and the source/drain features 220 during operation. In some embodiments, a portion of the isolation layer 207 is vertically interposed between the epitaxial structure 220N and the semiconductor layer 206, while another portion of the isolation layer 207 may cover a top portion of the epitaxial structure 220P grown on the semiconductor layer 206, as shown in the cross-sectional view of FIG. 13B. Alternatively, the isolation layer 207 is omitted as will be shown in accompanying with the embodiment of FIG. 18.

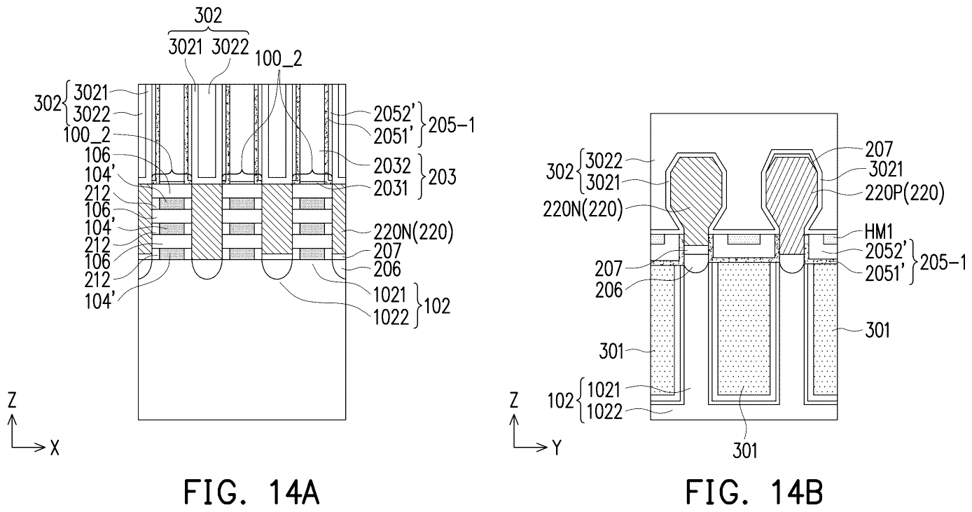

Referring to FIGS. 14A-14B and with reference to FIGS. 13A-13B, an interlayer dielectric (ILD) structure 302 may be formed to cover the epitaxial structures 220 and to surround the dummy gate structure 203 and the overlying mask layer 204, in accordance with some embodiments. In some embodiments, the ILD structure 302 includes an etch stop layer (ESL) 3021 lining the epitaxial structures 220, the dummy gate structure 203, and the overlying mask layer 204. As shown in the cross-sectional view of FIG. 14B, the protective layer HM1, the sidewall spacer layer 205-1, and the portion of epitaxial structures 220 protruded from the sidewall spacer layer 205-1 may be conformally lined with the ESL 3021. In some embodiments, the isolation layer 207 covering the top portion of the epitaxial structure 220P is covered by the ESL layer 3021. The ESL 3021 may include an oxygen-containing material or a nitrogen-containing material, such as SiN, SiCN, SiON, SiOx, SiOC, or the like, or a combination thereof. In some embodiments, a dielectric constant of the ESL layer 3021 is greater than a dielectric constant of the isolation structure 301 (e.g., the filling layer 3016 described in FIG. 3).

The ILD structure 302 may include a dielectric layer 3022 formed on the ESL 3021. In some embodiments, the materials of the ESL 3021 and the dielectric layer 3022 are different. The material for the dielectric layer 3022 may include oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), low-k material, porous dielectric material, and/or other suitable dielectric materials. For example, the dielectric layer 3022 has a dielectric constant that is about 3 to about 5. In some embodiments, after deposition of the dielectric layer 3022, the structure may be subject to a thermal process to anneal the dielectric layer 3022 of the ILD structure 302.

With continued reference to FIG. 14A and FIG. 13A, the etch stop material layer and the dielectric material layer are sequentially deposited, and then a planarization process may be performed to partially remove the etch stop material layer and the dielectric material layer. The remaining portions of the etch stop material layer and the dielectric material layer respectively form the ESL 3021 and the dielectric layer 3022. The planarization process may include a CMP process, a grinding process, an etching process, one or more other applicable processes, or a combination thereof. In some embodiments, the mask layer 204 including the first mask sublayer 2041 and the second mask sublayer 2042 is removed during the planarization process. After the planarization process, the dummy gate layer 2032 of the dummy gate structure 203 may be accessibly exposed. In some embodiments, after the planarization process, the top surfaces of the ESL 3021, the dielectric layer 3022, and the dummy gate layer 2032 of the dummy gate structure 203 are substantially level, within process variations.

Referring to FIG. 15A-15B and with reference to FIG. 14A, a removal process may be performed to remove the dummy gate structure 203 so as to form a recess 203R. The removal process may include one or more etching steps. For example, the etching step(s) that selectively etch the dummy gate structure 203 at a faster rate than the ILD structure 302 or the sidewall spacer layer 205-1. Next, the etched first semiconductor layers 104′ may be removed by etching (e.g., isotropic etching or the like). For example, using etchants which are selective to the materials of the etched first semiconductor layers 104′, while the second semiconductor layers 106, the ILD structure 302, the sidewall spacer layer 205-1, and the inner sidewall spacers 212 may remain relatively un-etched as compared to the etched first semiconductor layers 104′. During the step of removing the etched first semiconductor layers 104′, the epitaxial structures 220 may be protected by the ILD structure 302. After the removal of the etched first semiconductor layers 104′, respective bottom and top surfaces of each second semiconductor layers 106 and the top surface of the semiconductor substrate 102 may be exposed by recesses 104S.

Referring to FIGS. 16A-16B and with reference to FIG. 15A, a respective gate structure 240 may be formed around the second semiconductor layers 106 and fills the recesses 203R and 104S. The respective gate structure 240 may include a gate dielectric layer 244 and a gate metal layer 246 overlying the gate dielectric layer 244. As shown in the cross-sectional view of FIG. 16A, the gate structure 140 may extend between the adjacent second semiconductor layers 106. As shown in the cross-sectional view of FIG. 16B, the gate metal layer 246 may wrap around each second semiconductor layer 106, and the gate dielectric layer 244 may be disposed between the gate metal layer 246 and the second semiconductor layer 106, where the second semiconductor layers 106 (also referred to as semiconductor nanosheets or channel layers) function as channel regions.

The gate dielectric layer 244 may be a single high-k dielectric material or may include a stack of multiple high-k dielectric materials. Other suitable dielectric material(s) may be used to form the gate dielectric layer 244. In some embodiments, a dielectric constant of the gate dielectric layer 244 is greater than a dielectric constant of the ILD structure 302 (e.g., the dielectric layer 3022). The gate metal layer 246 may include a number of sections abutted to each other, each of the gate metal sections may extend not only along a horizontal plane (e.g., the X-Y plane), but also along the Z-direction. The gate metal layer 246 may include a stack of multiple metal materials. For example, one or more work function sublayers (not shown) are interposed between the gate dielectric layer 244 and the gate metal layer 246, wherein the work function sublayers may be formed separately for the n-type FET and the p-type FET which may use different metal layers.

With continued reference to FIGS. 16A-16B, the respective gate structure 240 may include an interfacial layer 242 formed between each second semiconductor layer 106 and the gate dielectric layer 244 and between the semiconductor substrate 102 and the bottommost gate dielectric layer 2441. As shown in the cross-sectional view of FIG. 16A, the interfacial layer 242 may be formed on the top and bottom surfaces of each second semiconductor layer 106 and also formed on the top surface 1021t of the respective bottom fin portion 1021 of the semiconductor substrate 102. The gate dielectric layer 244 may cover the interfacial layer 242 and may also be formed on the sidewalls of the inner sidewall spacers 212. As shown in the cross-sectional view of FIG. 16B, the interfacial layer 242 may wrap around each second semiconductor layer 106 and may be formed on the top surface 1021t of the respective bottom fin portion 1021, and the gate dielectric layer 244 may wrap around the interfacial layer 242. The bottommost gate dielectric layer 2441 may cover the interfacial layer 242 on the top surface 1021t of the respective bottom fin portion 1021 and extend to cover the top surface 301t of the isolation structures 301. The gate metal layer 246 may be formed in the rest space of the respective recess 203R and 104S. Note that FIG. 16B is a schematic cross-sectional view one of various stages of manufacturing the semiconductor device taken along line C-C of FIG. 4, and the protective layer HM1 and the underlying sidewall spacer layer 205-1 are not shown in the cross-sectional view of FIG. 16B.

In some embodiments, after sequentially depositing the materials of the gate structures 240, excess materials of the gate structures 240 are removed by a planarization process, so that the top surface 240t of the topmost gate structure 240 is substantially leveled (e.g., coplanar) with the top surface 302t of the ILD structure 302 and the top surface 205t the sidewall spacer layers 205-1, within process variations.

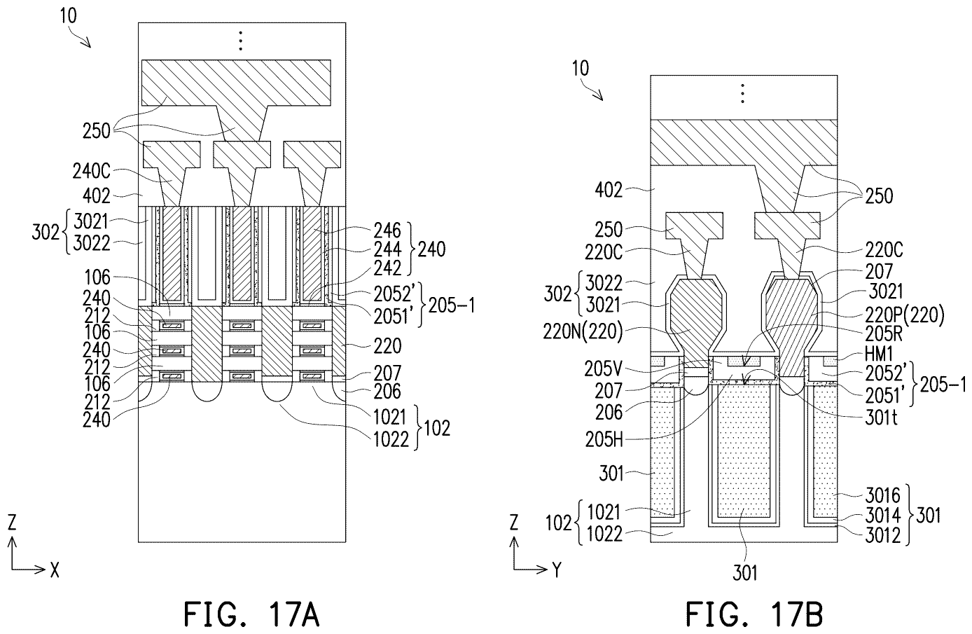

Referring to FIGS. 17A-17B and with reference to FIGS. 16A-16B, a dielectric layer 402 may be formed on the ILD structure 302. In some embodiments, the material of the dielectric layer 402 is the same as the material of the underlying dielectric layer 3022 of the ILD structure 302, so that no visible interface is formed therebetween. In alternative embodiments, the dielectric layer 402 has a different material than the underlying dielectric layer 3022. The material of the dielectric layer 402 may be selected from the group of candidate materials of the dielectric layer 3022. In some embodiments, gate contacts 240C and S/D contacts 220C are formed in the dielectric layer 402 to respectively connect the gate structures 240 and the epitaxial structures 220. The gate contacts 240C and the S/D contacts 220C may be made of or include cobalt, tungsten, ruthenium, titanium, molybdenum, one or more other suitable materials, or a combination thereof. As shown in the cross-sectional view of FIG. 17A, the respective gate contact 240C passes through the dielectric layer 402 to land on the topmost portion of the gate structures 240. As shown in the cross-sectional view of FIG. 17B, the respective S/D contact 220C passes through the dielectric layer 402, the dielectric layer 3022, and the ESL layer 3021 to land on the corresponding epitaxial structure 220. In some embodiments, the respective S/D contact 220C passes through the isolation layer 207 to be in contact with the corresponding epitaxial structure 220P.

With continued reference to FIGS. 17A-17B, conductive features 250 may be formed on the gate contacts 240C and the S/D contacts 220C and embedded in the dielectric layer 402. The conductive features 250 may include conductive pads, conductive vias, and conductive lines. For example, multiple dielectric layers 402 and multiple conductive features 250 may be formed. As a result, an interconnect structure is formed to be electrically coupled to the underlying gate structure 240 and the S/D features 220.

Still referring to FIGS. 17A-17B, a semiconductor device 10 may be provided. For example, the semiconductor device 10 includes the sidewall spacer layer 205-1 covering the top surface 301t of the isolation structure 301. As shown in the cross-sectional view of FIG. 17B, the sidewall spacer layer 205-1 may include first portions 205V and a second portion 205H connected to the first portions 205V, where the first portions 205V extend along the Z-direction and lining the bottoms of the adjacent S/D features 220, and the second portion 205H extends along the Y-direction and overlies the top surface 301t of the isolation structure 301. The respective epitaxial structure 220N/220P may have a portion overhanging the sidewall spacer layer 205-1. By configuring the sidewall spacer layer 205-1 on the isolation structure 301 for protection, the loss of the isolation structure 301 during the formation of the S/D recesses (see FIGS. 9A-9B) may be reduced or eliminated. It is appreciated that the loss of the isolation structure 301 may cause some issues, e.g., the dummy gate structure may be prone to collapse or fall down during the formation of the S/D recesses, the sidewall(s) of the bottom fin portions of the semiconductor substrate may be exposed and lack of protection, etc. By disposing the sidewall spacer layer 205-1 over the isolation structure 301, the issues associated with the loss of the isolation structure 301 may be reduced or eliminated.

The semiconductor device 10 may include the protective layer HM1 overlying the sidewall spacer layer 205-1. For example, the protective layer HM1 is inlaid in the second sublayer 2052′ of the sidewall spacer layer 205-1. In some embodiments, the sidewall spacer layer 205-1 has a recess 205R and the protective layer HM1 is disposed in the recess 205R. The top surfaces of the protective layer HM1 and the first portions 205V of the sidewall spacer layer 205-1 may be covered by the ESL layer 3021. The isolation structure 301 may be protected by the sidewall spacer layer 205-1 and the protective layer HM1. In some cases where the top surface of the isolation structure is not covered by the sidewall spacer layer and/or the protective layer, during the formation of the epitaxial structures, undesirable epitaxial growth on the exposed sidewall of the bottom fin portions of the semiconductor substrate may occur, and this growth may be characterized as a “mushroom” on account of its shape. The formation of the mushroom may cause the issues of leakage and parasitic capacitance. By disposing the sidewall spacer layer 205-1 and the protective layer HM1 horizontally between adjacent epitaxial structures 220 and vertically on the isolation structure 301, the issues of leakage and parasitic capacitance due to the formation of the mushroom may be reduced or eliminated.

It is appreciated that the isolation structure 301 may be subjected to one or more annealing step(s) to obtain a better quality of the isolation structure 301, and the isolation structure with the better quality may have a good resistance to some chemicals used in the etching/cleaning process during the formation of the S/D recesses (see FIGS. 9A-9B). The annealing step is one of high thermal budget processes during the fabrication of the semiconductor device 10, in some cases. However, the thermal instability of some materials at the high temperatures encountered results in degradation mechanisms, which can lead to degraded device performance. Accordingly, low thermal budget processes are preferred. The isolation structure 301 of the semiconductor device 10 may be subjected to a low thermal budget process, since the sidewall spacer layer 205-1 and the protective layer HM1 will be formed on the isolation structure 301 for protection during the formation of the S/D recesses. The thickness(es) of the first liner 3012 and/or the second liner 3014 of the isolation structure 301 may be reduced, leading to the potential density improvement.

FIG. 18 illustrates schematic cross-sectional view of a semiconductor device, in accordance with some embodiments. Referring to FIG. 18 and FIG. 17B, a semiconductor device 20 shown in FIG. 18 may be similar to the semiconductor device 10 described in FIG. 17B, and thus only differences therebetween are detailed. For example, the step of forming the isolation layer 207 (see FIGS. 13A-13B) is skipped during the fabrication of the semiconductor device 20. A portion of the isolation layer 207 formed between the epitaxial structure 220N and the semiconductor layer 206 may be omitted, and thus the epitaxial structure 220N may grow on the semiconductor layer 206. Another portion of the isolation layer 207 formed on the top of the epitaxial structure 220P may be omitted, and the ESL 3021′ may be directly formed on the top of the epitaxial structure 220P.

In some embodiments, during the step of forming the recesses 100R (see FIGS. 9A-9B) or the step of forming the lateral recesses 104R (see FIGS. 10A-10B), the protective layer HM1 is completely removed or only residues of the protective layer HM1 remain on the sidewall spacer layer 205-2. As the protective layer HM1 being removed from the second sublayer of the sidewall spacer layer, a portion of the sidewall spacer layer may be removed to form the sidewall spacer layer 205-2 having an uneven top surface 205t′. For example, the top surface 205t′ of the first sublayer 2051″ and the second sublayer 2052″ of the sidewall spacer layer 205-2 has a wavy cross-sectional profile that alternates between peaks 205tp and valleys 205tv, where the valleys 205tv correspond to the regions that was covered by the protective layer HM1, and the peaks 205tp are in proximity to the epitaxial structures 220 relative to the valleys 205tv. The ESL 3021′ may be conformally formed on the sidewall spacer layer 205-2 and covering the peaks 205tp and the valleys 205tv of the top surface 205t′.

According to some embodiments, a semiconductor device includes a first semiconductor fin and a second semiconductor fin extending along a first direction, an isolation structure disposed between the first semiconductor fin and the second semiconductor fin, a first epitaxial structure and a second epitaxial structure respectively disposed over the first semiconductor fin and the second semiconductor fin, and a sidewall spacer layer including a first portion and a second portion. Each of the first epitaxial structure and the second epitaxial structure includes a height measured along the first direction and a width measured along the second direction, and the height and the width are different. The first portion extends along the first direction and lines bottoms of the first epitaxial structure and the second epitaxial structure, the second portion extends along a second direction and is connected to the first portion, the second direction is substantially perpendicular to the first portion, and a portion of each of the first epitaxial structure and the second epitaxial structure overhangs the sidewall spacer layer.

According to some alternative embodiments, a semiconductor device includes a semiconductor fin protruding from a semiconductor substrate, an isolation structure disposed over the semiconductor substrate and surrounding the semiconductor fin, an epitaxial structure disposed over the semiconductor fin, a sidewall spacer layer covering a bottom sidewall of the epitaxial structure and a top surface of the isolation structure, and an etch stop layer overlying the epitaxial structure and the sidewall spacer layer. The top surface of the isolation structure is non-planar, the sidewall spacer layer includes a wavy cross-sectional profile, and a valley portion of the wavy cross-sectional profile is directly over the top surface of the isolation structure, and a dielectric constant of the etch stop layer is greater than a dielectric constant of the isolation structure.

According to some alternative embodiments, a method of forming a semiconductor device includes: recessing a semiconductor substrate to form a semiconductor fin protruding from the semiconductor substrate; forming an isolation structure on the semiconductor substrate to surround the semiconductor fin, where a top surface of the isolation structure is non-planar; forming a sidewall spacer layer on the isolation structure, where the sidewall spacer layer includes a wavy cross-sectional profile, and a valley portion of the wavy cross-sectional profile is directly over the top surface of the isolation structure; growing an epitaxial structure on the semiconductor fin, where a bottom sidewall of the epitaxial structure is covered by the sidewall spacer layer; and forming an etch stop layer on the epitaxial structure and the sidewall spacer layer, where a dielectric constant of the etch stop layer is greater than a dielectric constant of the isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor fin and a second semiconductor fin extending along a first direction;
an isolation structure disposed between the first semiconductor fin and the second semiconductor fin;
a first epitaxial structure and a second epitaxial structure respectively disposed over the first semiconductor fin and the second semiconductor fin, wherein each of the first epitaxial structure and the second epitaxial structure comprises a height measured along the first direction and a width measured along the second direction, and the height and the width are different; and
a sidewall spacer layer comprising a first portion and a second portion, the first portion extending along the first direction and lining bottoms of the first epitaxial structure and the second epitaxial structure, the second portion extending along a second direction and connected to the first portion, wherein the second direction is substantially perpendicular to the first portion, and a portion of each of the first epitaxial structure and the second epitaxial structure overhangs the sidewall spacer layer.

2. The semiconductor device of claim 1, further comprising:
a protective layer inlaid in the sidewall spacer layer and comprising a material different from a material of the sidewall spacer layer.

3. The semiconductor device of claim 2, further comprising:
an etch stop layer conformally overlying outermost surfaces of the first epitaxial structure and the second epitaxial structure and topmost surfaces of the sidewall spacer layer and the protective layer.

4. The semiconductor device of claim 1, further comprising:
an etch stop layer overlying outermost surfaces of the first epitaxial structure and the second epitaxial structure and a topmost surface of the sidewall spacer layer, wherein the topmost surface of the sidewall spacer layer comprises peaks and a valley connected to the peaks, and the etch stop layer conformally covers the peaks and the valley.

5. The semiconductor device of claim 1, further comprising:
channel regions disposed over the first semiconductor fin and separated from each other in the first direction, wherein the first epitaxial structure is adjacent to a sidewall of each of the channel regions.

6. The semiconductor device of claim 5, further comprising:
a gate structure wrapping around and extending between the channel regions, wherein a sidewall of a topmost portion of the gate structure is lined with the sidewall spacer layer.

7. The semiconductor device of claim 1, further comprising:
an isolation layer disposed between the first epitaxial structure and the first semiconductor fin in the first direction, wherein a sidewall of the isolation layer is covered by the sidewall spacer layer.

8. The semiconductor device of claim 1, further comprising:
an isolation layer overlying a top portion of the second epitaxial structure; and
a conductive contact penetrating through the isolation layer to connect the second epitaxial structure.

9. The semiconductor device of claim 1, wherein the sidewall spacer layer comprises:
a first sublayer lining the bottoms of the first and second epitaxial structures and a top surface of the isolation structure; and
a second sublayer conformally overlying the first sublayer.

10. A semiconductor device, comprising:
a semiconductor fin protruding from a semiconductor substrate;
an isolation structure disposed over the semiconductor substrate and surrounding the semiconductor fin, wherein a top surface of the isolation structure is non-planar;
an epitaxial structure disposed over the semiconductor fin;
a sidewall spacer layer covering a bottom sidewall of the epitaxial structure and a top surface of the isolation structure, the sidewall spacer layer comprising a wavy cross-sectional profile, and a valley portion of the wavy cross-sectional profile being directly over the top surface of the isolation structure; and
an etch stop layer overlying the epitaxial structure and the sidewall spacer layer, wherein a dielectric constant of the etch stop layer is greater than a dielectric constant of the isolation structure.

11. The semiconductor device of claim 10, further comprising:
a protective layer disposed on the valley portion of the sidewall spacer layer.

12. The semiconductor device of claim 11, wherein the sidewall spacer layer comprises:
a first sublayer lining the bottom sidewall of the epitaxial structure and the top surface of the isolation structure; and
a second sublayer conformally overlying the first sublayer, wherein a material of the protective layer is different from a material of the second sublayer.

13. The semiconductor device of claim 11, wherein the etch stop layer interfaces top surfaces of the sidewall spacer layer and the protective layer.

14. The semiconductor device of claim 10, wherein the etch stop layer is separated from the isolation structure at least by the sidewall spacer layer.

15. The semiconductor device of claim 10, wherein the etch stop layer conformally overlies the valley portion of the sidewall spacer layer.

16. A manufacturing method of a semiconductor device, comprising:
recessing a semiconductor substrate to form a semiconductor fin protruding from the semiconductor substrate;
forming an isolation structure on the semiconductor substrate to surround the semiconductor fin, wherein a top surface of the isolation structure is non-planar;
forming a sidewall spacer layer on the isolation structure, wherein the sidewall spacer layer comprises a wavy cross-sectional profile, and a valley portion of the wavy cross-sectional profile is directly over the top surface of the isolation structure;
growing an epitaxial structure on the semiconductor fin, wherein a bottom sidewall of the epitaxial structure is covered by the sidewall spacer layer; and
forming an etch stop layer on the epitaxial structure and the sidewall spacer layer, wherein a dielectric constant of the etch stop layer is greater than a dielectric constant of the isolation structure.

17. The manufacturing method of claim 16, further comprising:
forming a protective layer in the valley portion of the sidewall spacer layer before growing the epitaxial structure on the semiconductor fin.

18. The manufacturing method of claim 17, wherein forming the protective layer comprises:
depositing a protective material on the sidewall spacer layer;
performing a planarization process on the protective material, wherein at least a portion of the sidewall spacer layer is exposed by the protective material; and
etching the protective material after performing the planarization process.

19. The manufacturing method of claim 17, wherein forming the sidewall spacer layer comprises:
forming a first sublayer lining the bottom sidewall of the epitaxial structure and the top surface of the isolation structure; and
conformally forming a second sublayer on the first sublayer, wherein a material of the protective layer is different from a material of the second sublayer.

20. The manufacturing method of claim 16, wherein forming the etch stop layer comprises conformally lining the valley portion of the sidewall spacer layer with the etch stop layer.
